(19) United States
(12) Patent Application Publication
(10) Pub. No.: US 2018/0053718 A1
(43) Pub. Date: Feb. 22, 2018

(54) LAYER STACKING STRUCTURE, ARRAY SUBSTRATE AND DISPLAY DEVICE

(71) Applicant: BOE TECHNOLOGY GROUP CO., LTD., Beijing (CN)

(72) Inventor: Hongfei CHENG, Beijing (CN)

(73) Assignee: BOE Technology Group Co., Ltd., Beijing (CN)

(21) Appl. No.: 15/538,289

(22) PCT Filed: May 24, 2016
(86) PCT No.: PCT/CN2016/083119

§ 371 Date: Jun. 21, 2017

(30) Foreign Application Priority Data
Feb. 17, 2016 (CN) 201620126200.6

(51) Int. Cl. H01L 23/522; H01L 27/12; H01L 23/528; H01L 21/768

(52) U.S. Cl. CPC H01L 23/5226; H01L 27/124; H01L 21/76805; H01L 27/1262; H01L 23/528

(57) ABSTRACT

A layer stacking structure, an array substrate including the layer stacking structure and a display device including the array substrate are provided. The layer stacking structure, including: a base substrate; a first conductive layer, a first insulating layer, a second conductive layer and a second insulating layer sequentially stacked in a direction away from the base substrate, wherein, the first conductive layer and the second conductive layer overlap with each other in an overlapping region, a recessed portion arranged in the overlapping region, wherein, the first conductive layer and the second conductive layer are electrically connected with each other through the conductive connection component.

### TECHNICAL FIELD

Embodiments of the present disclosure relate to a layer stacking structure, an array substrate including the layer stacking structure and a display device including the array substrate.

### BACKGROUND

Generally, in a manufacturing process of an electronic product, generally two conductive layers located in different layers need to be electrically connected. For example, in a peripheral circuit region of an array substrate of a display device, two conductive layers located in different layers are electrically connected, for example, through two via holes and one connection conductive layer; one of the two conductive layers is exposed through one of the via holes, the other one of the two conductive layers is exposed through the other one of the via holes, the two conductive layers located in different layers are electrically connected by the connection conductive layer through the two via holes, but the connection structure is large in occupied area and the structure is relatively complex.

### SUMMARY

Embodiments of the present disclosure provides a layer stacking structure, an array substrate including the layer stacking structure and a display device including the array substrate, capable of solving the technical problem that the large and relatively complicated connection structure for different conductive layers in the prior art.

An embodiments of the present disclosure provides a layer stacking structure, including: a base substrate; a first conductive layer, a first insulating layer, a second conductive layer and a second insulating layer sequentially stacked in a direction away from the base substrate, wherein, the first conductive layer and the second conductive layer overlap with each other in an overlapping region; a recessed portion arranged in the overlapping region, including: a first via hole passing through the first insulating layer; a second via hole passing through the second conductive layer; and a third via hole passing through the second insulating layer, wherein, the first via hole, the second via hole and the third via hole are communicated with each other; and a conductive connection component, extending to pass through the third via hole, the second via hole and the first via hole of the recessed portion, wherein, the first conductive layer and the second conductive layer are electrically connected with each other through the conductive connection component, wherein, the second conductive layer has at least one protrusion portion protruding towards an interior of the second via hole on a sidewall of the second via hole.

For example, in the layer stacking structure provided by an embodiment of the present disclosure, the conductive connection component is in direct contact with the second conductive layer on the sidewall of the second via hole, and the conductive connection component is in direct contact with an upper surface of the first conductive layer at a bottom of the first via hole

For example, in the layer stacking structure provided by an embodiment of the present disclosure, an orthogonal projection of the second via hole on the base substrate is located within an orthogonal projection of the third via hole on the base substrate, and the conductive connection component is in direct contact with an upper surface of the second conductive layer at a bottom of the third via hole.

For example, in the layer stacking structure provided by an embodiment of the present disclosure, the orthogonal projection of the second via hole on the base substrate is located within a orthogonal projection of the first via hole on the base substrate, and the conductive connection component is in direct contact with a lower surface of the second conductive layer at a top of the first via hole.

For example, in the layer stacking structure provided by an embodiment of the present disclosure, the recessed portion further includes a fourth via hole passing through the first conductive layer, the fourth via hole is communicated with the first via hole, and the conductive connection component extends to pass through the fourth via hole so as to be in direct contact with an upper surface of the base substrate at a bottom of the fourth via hole.

For example, in the layer stacking structure provided by an embodiment of the present disclosure, the first via hole, the second via hole and the third via hole are completely filled by the conductive connection component.

For example, in the layer stacking structure provided by an embodiment of the present disclosure, the second via hole has a first sidewall and a second sidewall opposite to each other, the at least one protrusion portion includes at least one first protrusion portion protruding towards the second sidewall on the first sidewall, and at least one second protrusion portion protruding towards the first sidewall on the second sidewall.

For example, in the layer stacking structure provided by an embodiment of the present disclosure, the second via hole further has a third sidewall and a fourth sidewall opposite to each other, the at least one protrusion portion further includes at least one third protrusion portion protruding towards the fourth sidewall on the third sidewall, and at least one fourth protrusion portion protruding towards the third sidewall on the fourth sidewall.

For example, in the layer stacking structure provided by an embodiment of the present disclosure, the first protrusion portion, the second protrusion portion, the third protrusion portion and the fourth protrusion portion are not in contact with each other.

For example, in the layer stacking structure provided by an embodiment of the present disclosure, the orthogonal projection of the first via hole on the base substrate coincides with the orthogonal projection of the second via hole on the base substrate.

For example, in the layer stacking structure provided by an embodiment of the present disclosure, the conductive connection component is formed by a transparent conductive metal oxide.

For example, in the layer stacking structure provided by an embodiment of the present disclosure, a planar shape of the at least one protrusion portion is square, rectangular, semicircular or polygonal.

For example, in the layer stacking structure provided by an embodiment of the present disclosure, the first via hole, the second via hole and the third via hole are partially filled with the conductive connection component.

At least one embodiment of the present disclosure further provides an array substrate, including the layer stacking structure according to any one of claims 1 to 13, and a pixel unit formed on the base substrate, wherein, the pixel unit is located in a display region of the base substrate, and the layer stacking structure is located in a peripheral circuit region surrounding the display region.

For example, in the array substrate provided by an embodiment of the present disclosure, the pixel unit includes a thin film transistor and a pixel electrode, the thin film transistor includes a gate electrode, a gate electrode insulating layer, an active layer, a source electrode and a drain electrode, and a passivation layer sequentially stacked in the direction away from the base substrate, the first conductive layer and the gate electrode are arranged on a same layer and are formed by a same material, the first insulating layer and the gate electrode insulating layer are on a same layer, the second conductive layer and the source electrode and the drain electrode are arranged on a same layer and are formed by a same material, the second insulating layer and the passivation layer are on a same layer, and the conductive connection component and the pixel electrode are formed by a same material.

For example, in the array substrate provided by an embodiment of the present disclosure, a semiconductor pattern layer is further arranged between the second conductive layer and the first insulating layer, the semiconductor pattern layer and the active layer are arranged on a same layer and are formed by a same material, the recessed portion further includes a fifth via hole passing through the semiconductor pattern layer, the fifth via hole is communicated with the first via hole and the second via hole, and the conductive connection component extends to pass through the fifth via hole.

At least one embodiment of the present disclosure further provides a display device, including the array substrate described above.

In the layer stacking structure, the array substrate including the layer stacking structure and the display device including the array substrate provided by the embodiments of the present disclosure, two conductive layers in different layers are connected with each other through the conductive connection component in the same recessed portion. Thus, reliable electrical connection is achieved through a structure which is simple and small in occupied area.

### BRIEF DESCRIPTION OF THE DRAWINGS

In order to clearly illustrate technical solutions of the embodiments of the disclosure, drawings of the embodiments will be introduced simply, and it is obvious that the described drawings only relate to some of the embodiments of the present disclosure, but are not limitative of the present disclosure. Respective film layers in the drawings are not drawn according to an actual proportion. The drawings only show structures closely related to the embodiments of the present disclosure, and other structures can refer to general design on a basis of the embodiments of the present disclosure.

FIG. 1 is a schematic plan view of a layer stacking structure provided by Embodiment I of the present disclosure;

FIG. 2 is a schematic sectional view of the layer stacking structure shown by FIG. 1 along an line A-A2;

FIG. 3 is a schematic sectional view of a variant of the layer stacking structure provided by Embodiment I of the present disclosure;

FIG. 4 is a schematic sectional view of another variant of the layer stacking structure provided by Embodiment I of the present disclosure;

FIG. 5 is a schematic plan view of a layer stacking structure provided by Embodiment II of the present disclosure;

FIG. 6 is a schematic sectional view of the layer stacking structure shown by FIG. 5 along an line A1-A2;

FIG. 7 is a schematic sectional view of the layer stacking structure shown by FIG. 5 along a line B1-B2;

FIG. 8 is a schematic plan view of a layer stacking structure provided by an example of Embodiment II of the present disclosure;

FIG. 9 is a schematic sectional view of the layer stacking structure shown by FIG. 8 along an line A1-A2;

FIG. 10 is a schematic plan view of a layer stacking structure provided by Embodiment III of the present disclosure;

FIG. 11 is a schematic plan view of a layer stacking structure provided by Embodiment IV of the present disclosure;

FIG. 12 is a schematic sectional view of the layer stacking structure shown by FIG. 11 along a line B1-B2;

FIG. 13 is a schematic plan view of an array substrate provided by Embodiment V of the present disclosure; and

FIG. 14 is a schematic sectional view of the array substrate shown by FIG. 13 along a C1-C2 line.

### DETAILED DESCRIPTION

In order to clearly illustrate purposes, technical solutions and advantages of the embodiments of the disclosure, the technical solutions of the embodiments of the present disclosure will be described in a clearly and fully understandable way in connection with the drawings in the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure. In a case of no conflict, characteristics in different embodiments of the present disclosure can be combined with each other.

Unless otherwise defined, the technical terms or scientific terms here should be of general meaning as understood by those ordinarily skilled in the art. In the present disclosure, words such as “first”, “second” and the like do not denote any order, quantity, or importance, but rather are used for distinguishing different components. Similarly, words such as “one”, “a/an” or “the” or the like do not denote quantitative limitation, but rather indicate there is at least one. Words such as “include” or “comprise” and the like denote that elements or objects appearing before the words of “include” or “comprise” cover the elements or the objects enumerated after the words of “include” or “comprise” or equivalents thereof, not exclusive of other elements or objects. Words such as “connected” or “connecting” and the like are not limited to physical or mechanical connections, but may include electrical connection, either direct or indirect. Words such as “up”, “down”, “left”, “right”, “top”, “bottom” and the like are only used for expressing relative positional relationship, when the absolute position is a described object is changed, the relative positional relationship may also be correspondingly changed.

At least one embodiment of the present disclosure provides a layer stacking structure, an array substrate including the layer stacking structure and a display device including the array substrate. The layer stacking structure, comprises: a base substrate; a first conductive layer, a first insulating layer, a second conductive layer and a second insulating layer sequentially stacked in a direction away from the base substrate, wherein, the first conductive layer and the second conductive layer overlap with each other in an overlapping region; a recessed portion arranged in the overlapping region, including: a first via hole passing through the first insulating layer; a second via hole passing through the second conductive layer; and a third via hole passing through the second insulating layer, wherein, the first via hole, the second via hole and the third via hole are communicated with each other; and a conductive connection component, extending to pass through the third via hole, the second via hole and the first via hole of the recessed portion, wherein, the first conductive layer and the second conductive layer are electrically connected with each other through the conductive connection component.

In the layer stacking structure, the array substrate including the layer stacking structure and the display device including the array substrate provided by the above embodiments, two conductive layers located in different layers are electrically connected with each other by means of the conductive connection component extending to pass through a same recessed portion, and therefore reliable electrical connection is achieved through a structure which is simple and small in occupied area.

### Embodiment I

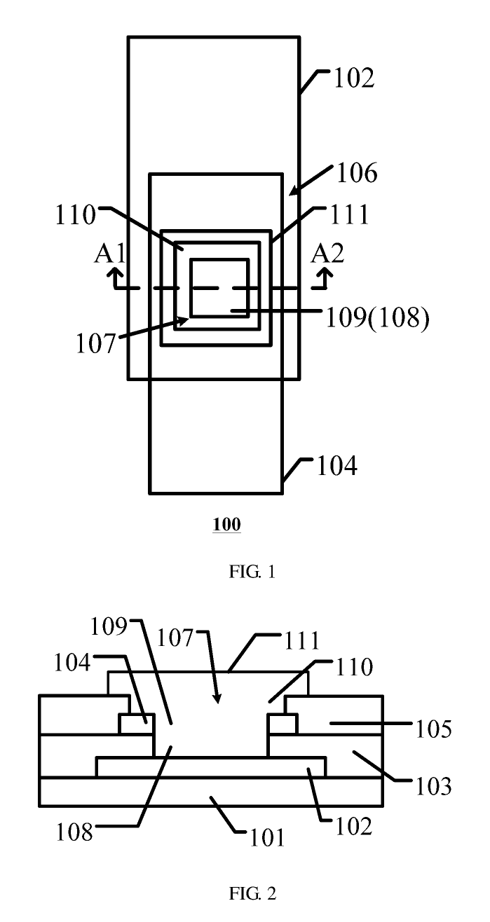

FIG. 1 is a schematic plan view of a layer stacking structure provided by Embodiment I of the present disclosure; and FIG. 2 is a schematic sectional view of the layer stacking structure of FIG. 1 along a line A1-A2.

Referring to FIG. 1 and FIG. 2, the layer stacking structure 100, includes: a base substrate 101; a first conductive layer 102, a first insulating layer 103, a second conductive layer 104 and a second insulating layer 105 sequentially stacked in a direction away from the base substrate 101, wherein, the first conductive layer 102 and the second conductive layer 104 overlap with each other in a region 106 (the region 106 can be referred to as an overlapping region); a recessed portion 107 arranged in the overlapping region 106, the recessed portion 107 including: a first via hole 108 passing through the first insulating layer 103; a second via hole 109 passing through the second conductive layer 104; and a third via hole 110 passing through the second insulating layer 105, wherein, the first via hole 108, the second via hole 109 and the third via hole 110 are communicated with each other; and a conductive connection component 111, extending to pass through the third via hole 110, the second via hole 109 and the first via hole 108 of the recessed portion 107, wherein, the first conductive layer 102 and the second conductive layer 104 are electrically connected with each other through the conductive connection component 111. For example, respective planar shapes of the first via hole 108, the second via hole 109 and the third via hole 110 can be square, rectangular, elliptical, polygonal or other irregular shapes. Herein, the first insulating layer 103 can include only one insulating layer or can include a plurality of insulating layers. Similarly, the second insulating layer 105 can include only one insulating layer or can include a plurality of insulating layers.

For example, in the layer stacking structure provided by the embodiment, referring to FIG. 1 and FIG. 2, for example, the recessed portion 107 formed by the first via hole 108, the second via hole 109 and the third via hole 110 is completely filled with the conductive connection component 111. The conductive connection component 111 is in direct contact with the second conductive layer 104 on a sidewall of the second via hole 109. For example, the conductive connection component 111 completely covers the sidewall of the second via hole 109 in the second conductive layer 104. The conductive connection component 111 is in direct contact with an upper surface of the first conductive layer 102 at a bottom of the first via hole 108, and for example, the conductive connection component 111 completely covers an upper surface of the first conductive layer 102 exposed by the first via hole 108 in the first insulating layer 103.

For example, as shown in FIG. 2, a orthogonal projection of the first via hole 108 on the base substrate 101 coincides with a orthogonal projection of the second via hole 109 on the base substrate 101. That is, a size of the orthogonal projection of the first via hole 108 on the base substrate 101 is equal to a size of the orthogonal projection of the second via hole 109 on the base substrate 101, and the orthogonal projection of the second via hole 109 on the base substrate 101 completely coincides with a range of the orthogonal projection of the first via hole 108 on the base substrate 101.

For example, in the layer stacking structure provided by the present embodiment, referring to FIG. 1 and FIG. 2, the orthogonal projection of the second via hole 109 in the second conductive layer 104 on the base substrate 101 is located within a orthogonal projection of the third via hole 110 in the second insulating layer 105 on the base substrate 101, That is, a size of the orthogonal projection of the second via hole 109 on the base substrate 101 is smaller than a size of the orthogonal projection of the third via hole 110 on the base substrate 101, and the orthogonal projection of the second via hole 109 on the base substrate 101 is overall located in a range of the orthogonal projection of the third via hole 110 on the base substrate 101. For example, an edge of the orthogonal projection of the second via hole 109 on the base substrate 101 is completely separated from an edge of the orthogonal projection of the third via hole 110 on the base substrate 101. In this case, the conductive connection component 111 is, for example, in direct contact with an upper surface of the second conductive layer 104 at a bottom of the third via hole 110 in the second insulating layer 105. In this way, the second conductive layer 104 is in direct contact with the conductive connection component 111 on the upper surface and a side surface, which is favorable for improving an electrical connection performance of the second conductive layer 104 and the conductive connection component 111.

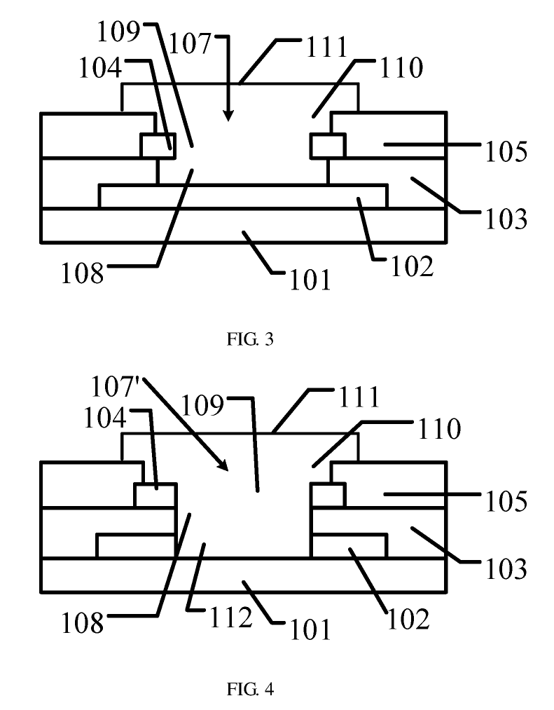

For example, FIG. 3 shows a schematic sectional view of a variant of the layer stacking structure provided by the above Embodiment I of the present disclosure. The layer stacking structure shown by FIG. 3 can have a structure substantially same as the layer stacking structure shown by FIG. 1 and FIG. 2 as provided by Embodiment I, except for a first opening 108. Thus, repeated description of same parts will be omitted herein, and same terms and same reference signs are used for showing same parts.

In the layer stacking structure shown by FIG. 3, the orthogonal projection of the second via hole 109 in the second conductive layer 104 on the base substrate 101 is located within the orthogonal projection of the first via hole 108 in the first insulating layer 103 on the base substrate 101. That is, a size of the orthogonal projection of the second via hole 109 on the base substrate 101 is smaller than a size of the orthogonal projection of the first via hole 108 on the base substrate 101, and the orthogonal projection of the second via hole 109 on the base substrate 101 is overall located within a range of the orthogonal projection of the third via hole 110 on the base substrate 101. For example, an edge of the orthogonal projection of the second via hole 109 on the base substrate 101 is completely separated from an edge of the orthogonal projection of the first via hole 108 on the base substrate 101. In this case, for example, the conductive connection component 111 is in direct contact with a lower surface of the second conductive layer 104 at a top of the first via hole 108 in the first insulating layer 103. In this way, in the layer stacking structure shown by FIG. 3, the second conductive layer 104 is in direct contact with the conductive connection component 111 on the upper surface, the lower surface and the side surface, which is favorable for improving the electrical connection performance of the second conductive layer 104 and the conductive connection component 111.

For example, FIG. 4 shows another variant schematic sectional view of the layer stacking structure provided by the above Embodiment I of the present disclosure. The layer stacking structure shown by FIG. 4 can have a structure substantially same as the layer stacking structure shown by FIG. 1 and FIG. 2 as provided by Embodiment I, except for a fourth opening 112 and a recessed portion 107′. Thus, repeated description of same parts will be omitted herein, and same terms and same reference signs are used for showing same parts.

In the layer stacking structure shown by FIG. 4, in addition to the first via hole 108 in the first insulating layer 103, the second via hole 109 in the second conductive layer 104 and the third via hole 110 in the second insulating layer 105, the recessed portion 107′ further includes a fourth via hole 112 passing through the first conductive layer 102. The fourth via hole 112 is communicated with the first via hole 108, That is, the first via hole 108, the second via hole 109, the third via hole 110 and the fourth via hole 112 are communicated with each other. In the embodiment, the recessed portion 107′, for example refers to a recessed region formed by the first via hole 108, the second via hole 109, the third via hole 110 and the fourth via hole 112.

The conductive connection component 111 extends to pass through the third via hole 110, the second via hole 109, the first via hole 108 and the fourth via hole 112 so as to be in direct contact with an upper surface of the base substrate 101 at a bottom of the fourth via hole 112. For example, the recessed portion formed by the first via hole 108, the second via hole 109, the third via hole 110 and the fourth via hole 112 is completely filled by the conductive connection component 111. For example, in an example, the base substrate 101 is glass, the first conductive layer 102 is a metal layer, and a material of the conductive connection component 111 is a transparent conductive oxide (such as, indium tin oxide). In this case, for example, adhesion stability of the conductive connection component 111 and the base substrate 101 is superior to that of the conductive connection component 111 and the first conductive layer. Thus, in this case, in the layer stacking structure shown by FIG. 4, because of presence of the fourth via hole 112, the adhesion stability of the conductive connection component 111 on the base substrate 101 can be effectively improved.

### Embodiment II

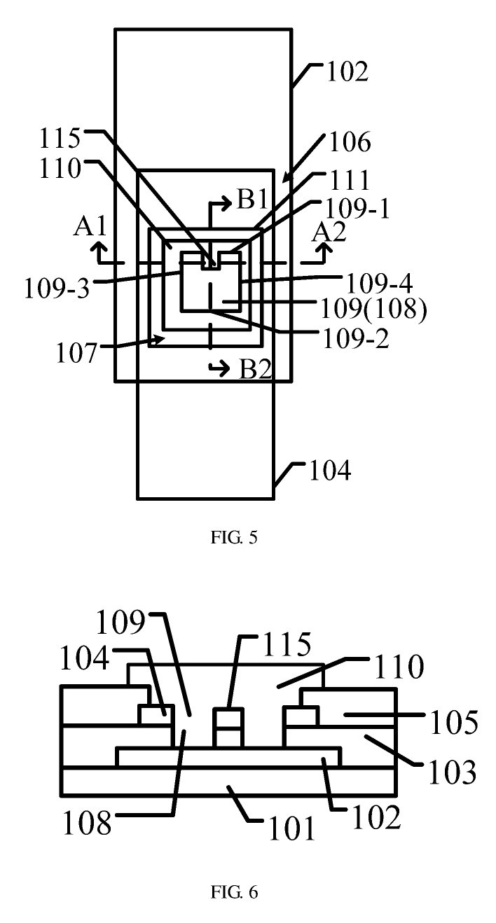

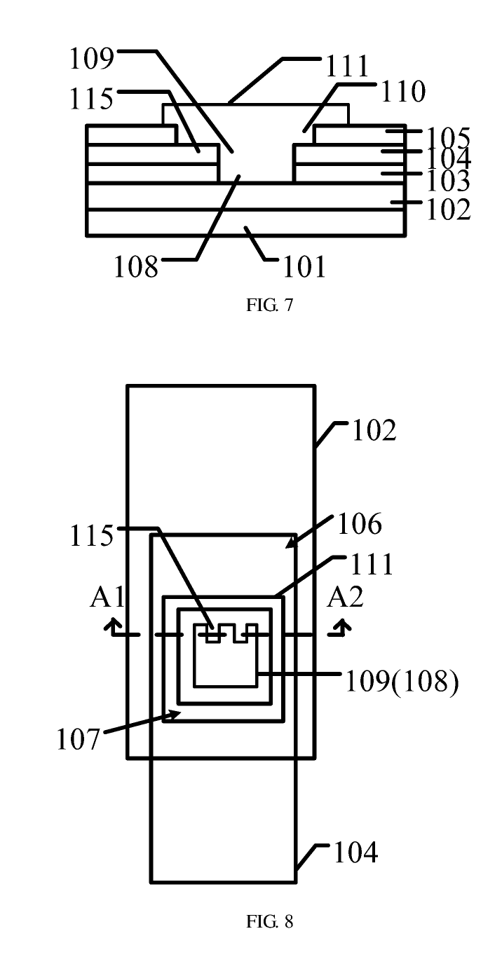

FIG. 5 shows a schematic plan view of a layer stacking structure provided by Embodiment II of the present disclosure; FIG. 6 shows a schematic sectional view of the layer stacking structure in FIG. 5 along a line A1-A2; and FIG. 7 shows a schematic sectional view of the layer stacking structure in FIG. 5 along a line B1-B2.

The layer stacking structure provided by Embodiment II of the present disclosure can have a structure substantially same as the layer stacking structure provided by Embodiment I, except for a first protrusion portion 115. Thus, repeated description of same parts will be omitted herein, and same terms and same reference signs are used for showing same parts.

In the layer stacking structure provided by the present embodiment, as shown in FIG. 5, the second via hole 109 in the second conductive layer 104 has a first sidewall 109-1, a second sidewall 109-2, a third sidewall 109-3 and a fourth sidewall 109-4. The first sidewall 109-1 and the second sidewall 109-2 of the second via hole 109 are opposite to each other; the third sidewall 109-3 and the fourth sidewall 109-4 of the second via hole 109 are opposite to each other. As shown in FIGS. 5 to 7, the second conductive layer 104 has one first protrusion portion 115 on the first sidewall 109-1 of the second via hole 109, protruding towards an interior of the second via hole 109. For example, the first protrusion portion 115 of the second conductive layer 104 on the first sidewall 109-1 protrudes towards the second sidewall 109-2.

A contact area between the conductive connection component 111 and the second conductive layer 104 is increased because of presence of the first protrusion portion 115, which thus can improve an electrical connection performance of the conductive connection component 111 and the second conductive layer 104. For example, a planar shape of the first protrusion portion 115 can be square, rectangular, semicircular, polygonal, or any other irregular shape.

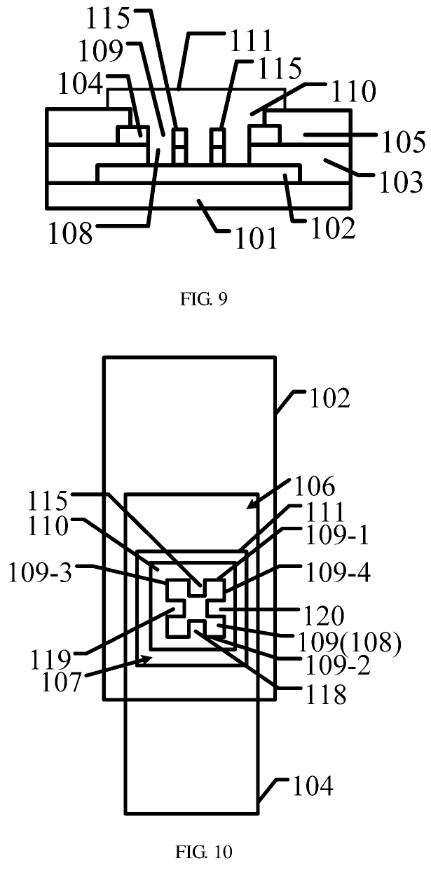

Although in the layer stacking structure shown by FIG. 5, FIG. 6 and FIG. 7, the second conductive layer 104 has one first protrusion portion 115 on the first sidewall 109-1 of the second via hole 109, but it should be understood that the number of the first protrusion portion 115 of the second conductive layer 104 on the first sidewall 109-1 is not limited in the present embodiment. That is, the second conductive layer 104 can have a plurality of first protrusion portions 115 on the first sidewall 109-1 of the second via hole 109. In an example, as shown in FIG. 8 and FIG. 9, the second conductive layer 104 is provided with two first protrusion portions 115 on the first sidewall 109-1 of the second via hole 109, protruding towards the second sidewall 109-2. The two first protrusion portions 115, for example, both protrude towards an interior of the second via hole 109. In this way, a contact area between the conductive connection component 111 and the second conductive layer 104 is further increased, or contact points between the conductive connection component 111 and the second conductive layer are further increased, thus improving the electrical connection performance of the conductive connection component 111 and the second conductive layer 104. Similarly, the second conductive layer 104 can be provided with more first protrusion portions 115 on the first sidewall 109-1 of the second via hole 109, protruding towards the second sidewall 109-2.

### Embodiment III

FIG. 10 shows a schematic plan view of a layer stacking structure provided by Embodiment III of the present disclosure; the layer stacking structure provided by Embodiment III of the present disclosure can have a structure substantially same as the layer stacking structure provided by Embodiment II, except for a second protrusion portion 118, a third protrusion portion 119 and a fourth protrusion portion 120. Thus, repeated description of same parts will be omitted herein, and same terms and same reference signs are used for showing same parts.

As shown in FIG. 10, in the layer stacking structure provided by the present embodiment, for example, the above four sidewalls are sequentially connected in a sequence of the first sidewall 109-1, the third sidewall 109-3, the second sidewall 109-2, the fourth sidewall 109-4 and the first sidewall 109-1. The third sidewall 109-3 is connected with the first sidewall 109-1 and the second sidewall 109-2 on one side of the first sidewall 109-1 and the second sidewall 109-2. As shown in FIG. 10, the third sidewall 109-3 is connected with the first sidewall 109-1 and the second sidewall 109-2 on a left side of the first sidewall 109-1 and the second sidewall 109-2; the fourth sidewall 109-4 is connected with the first sidewall 109-1 and the second sidewall 109-2 on the other side of the first sidewall 109-1 and the second sidewall 109-2. As shown in FIG. 10, the fourth sidewall 109-4 is connected with the first sidewall 109-1 and the second sidewall 109-2 on a right side of the first sidewall 109-1 and the second sidewall 109-2. The second conductive layer 104 has one second protrusion portion 118 on the second sidewall 109-2, protruding towards the first sidewall 109-1; the second conductive layer 104 has one third protrusion portion 119 on the third sidewall 109-3, protruding towards the fourth sidewall 109-4; the second conductive layer 104 has one fourth protrusion portion 120 on the fourth sidewall 109-4, protruding towards the third sidewall 109-3. The first protrusion portion 115, the second protrusion portion 118, the third protrusion portion 119 and the fourth protrusion portion 120 all protrude towards an interior of the second via hole 109.

In the layer stacking structure shown by FIG. 10, the second conductive layer 104 has four protrusion portion on four sidewalls of the second via hole 109 respectively. In another example, the second conductive layer 104 can have one or more protrusion portions on each of the four sidewalls of the second via hole 109. Planar shapes of respective protrusion portions 115, 118, 119 and 120 can be square, rectangular, semicircular, polygonal, or other irregular shapes.

In addition, the form and the number of the sidewalls of the second via hole 109 are not limited by the embodiment of the present disclosure, for example, the second via hole 109 can have three sequentially connected sidewalls, or six sequentially connected sidewalls. For example, the second conductive layer 104 has one protrusion portion on each sidewall of the second via hole 109 protruding towards an interior of the second via hole 109. Each sidewall of the second via hole 109 can be a flat surface or a curved surface (for instance, an arc-shaped surface and a bent surface).

For example, as shown in FIG. 10, the first protrusion portion 115, the second protrusion portion 118, the third protrusion portion 119 and the fourth protrusion portion 120 are not in contact with each other, which thus is favorable for improving an electrical connection performance of the conductive connection component 111 and the second conductive layer 104.

### Embodiment IV

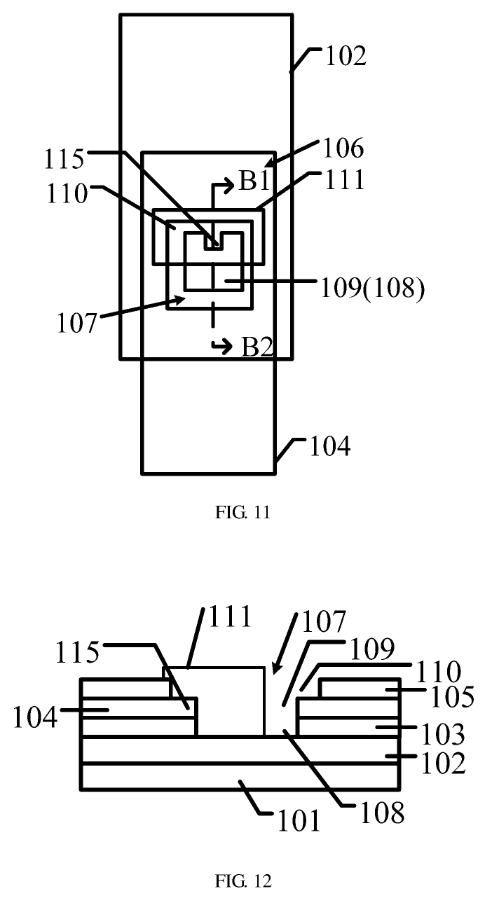

FIG. 11 is a schematic plan view of a layer stacking structure provided by Embodiment IV of the present disclosure; FIG. 12 is a schematic sectional view of the layer stacking structure shown by FIG. 11 along a line B1-B2. The layer stacking structure provided by Embodiment IV of the present disclosure can have a structure substantially same as the layer stacking structure provided by Embodiment II, except for the conductive connection component 111. Thus, repeated description of same parts will be omitted herein, and same terms and same reference signs are used for showing same parts.

For example, as shown in FIG. 11 and FIG. 12, the conductive connection component 111 partially covers the recessed portion 107. In the embodiment, for example, the recessed portion 107 is formed by the first via hole 108 in the first insulating layer, the second via hole 109 in the second conductive layer 104 and the third via hole 110 in the second insulating layer 105. The conductive connection component 111 extends to pass through the third via hole 110, the second via hole 109 and the first via hole 108 to partially fill the recessed portion 107.

What should be understood is that, a filling degree of the conductive connection component 111 in the recessed portion is not limited by the embodiment of the present disclosure, a connection manner of the conductive connection component 111 with the first conductive layer 102 and the second conductive layer 104 is not limited, either, and, as long as electrical connection of the first conductive layer 102 and the second conductive layer 104 is achieved through the conductive connection component 111.

### Embodiment V

The embodiment provides an array substrate, including a layer stacking structure provided by any one of the above embodiments, and a pixel unit formed on the base substrate, wherein, the pixel unit is located in a display region of the base substrate, and the layer stacking structure is located in a peripheral circuit region surrounding the display region.

For example, the array substrate provided by the embodiment of the present disclosure is configured for forming a display device. The array substrate includes a plurality of gate lines and a plurality of data lines, the gate lines and the data lines are intersected with each other, thus defining pixel units arranged in a matrix. For example, each pixel unit includes a thin film transistor as a switch element and a pixel electrode for controlling arrangement of liquid crystals. Or, the pixel electrode of each pixel unit of the array substrate is configured for driving an organic light-emitting material to emit light so as to perform display operation as an anode or a cathode.

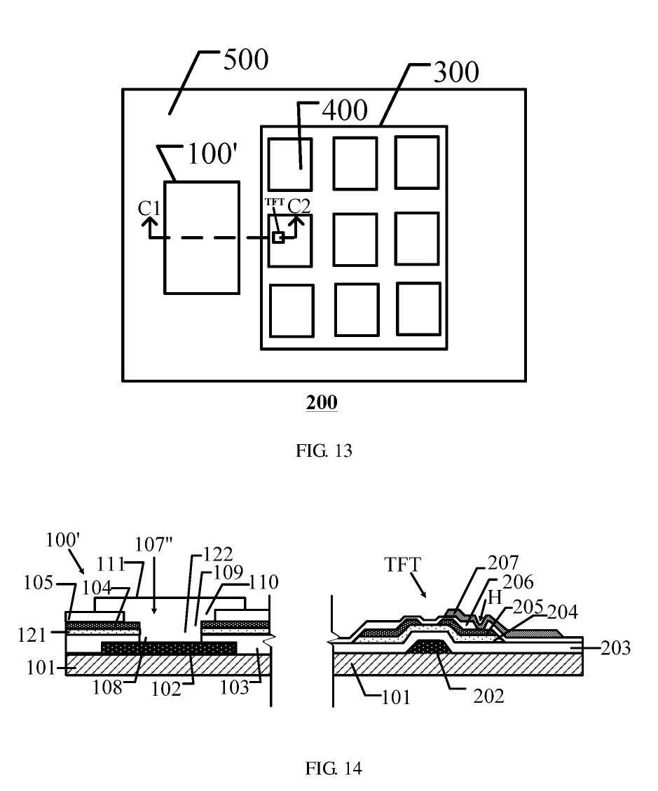

FIG. 13 shows a schematic plan view of the array substrate provided by Embodiment V of the present disclosure; and FIG. 14 is a schematic sectional view of the array substrate as shown by FIG. 13 along a line C1-C2. The array substrate 200 provided by the embodiment, for example, as shown in FIG. 13, includes a layer stacking structure 100′ and a plurality of pixel units 400 arranged in a matrix manner. The layer stacking structure 100′ can have a structure substantially same as the layer stacking structure 100 shown by FIG. 1 and FIG. 2, except for a semiconductor pattern layer 12. Thus, repeated description of same parts will be omitted herein, and same terms and same reference signs are used for showing same parts. The pixel unit 400 is formed on the base substrate 101. The pixel unit 400 is located in a display region 300 of the base substrate 101, and the layer stacking structure 100′ is located in a peripheral circuit region 500 surrounding the display region 300. Herein, the display region 300 refers to a distribution region of the pixel unit 400.

For example, as shown in FIG. 14, the pixel unit 400 includes a thin film transistor TFT and a pixel electrode 207. The thin film transistor TFT includes a gate electrode 202, a gate electrode insulating layer 203, an active layer 204, a source electrode and a drain electrode 205, and a passivation layer 206 sequentially arranged in a stacking manner in a direction away from the base substrate. The first conductive layer 102 and the gate electrode 202 are arranged on a same layer and are formed by a same material; the first insulating layer 103 and the gate electrode insulating layer 203 are on a same layer; the second conductive layer 104 and the source electrode and the drain electrode 205 are arranged on a same layer and are formed by a same material; the second insulating layer 105 and the passivation layer 206 are on a same layer; the conductive connection component 111 and the pixel electrode 207 are formed by a same material.

As shown in FIG. 14, a semiconductor pattern layer 121 is further arranged between the second conductive layer 104 and the first insulating layer 103, and the semiconductor pattern layer 121 and the active layer 204 are arranged on a same layer and are formed by a same material. A recessed portion 107″ further includes a fifth via hole 122 passing through the semiconductor pattern layer 121. The fifth via hole 122 is communicated with a first via hole 108 and a second via hole 109, and the conductive connection component 111 extends to pass through the fifth via hole 122. What can be understood is that the semiconductor pattern layer 121 is not indispensable. In addition, the array substrate can include the layer stacking structure provided by any one of the above embodiments of the present disclosure.

Hereinafter, a manufacturing method of the array substrate shown by FIG. 13 and FIG. 14 is described. For example, the manufacturing method can optionally include following steps in sequence:

S101: forming the first conductive layer and the gate electrode on the base substrate 101;

A first metal thin film is deposited on the base substrate 101 by sputtering, for example, a material of the first metal thin film can be Cu, Al, Mo, Ti, Cr, W or an alloy of the metal materials. Then, a single patterning process (including photoresist coating, exposure, development, etching, photoresist stripping and other steps) is executed on the first metal thin film so as to form the first conductive layer 102 and the gate electrode 202 which are on the same layer and formed by the same material. The first conductive layer 102 and the gate electrode 202 can be of a single layer structure, and can also be of a multi-layer structure, such as Mo/Al/Mo, Ti/Cu/Ti, MoTi/Cu, Ti/Cu/Mo and the like.

S102: forming a first insulating thin film on the base substrate with the first conductive layer and the gate electrode formed thereon;

The first insulating thin film such as silicon nitride or silicon oxide is deposited on the base substrate 101 where the first conductive layer 102 and the gate electrode 202 are formed through a Plasma Enhanced Chemical Vapor Deposition (PECVD) process. The first insulating thin film can serve as a gate insulating layer 203 and is used for further forming the first insulating layer 103 subsequently. When the step is completed, the first insulating thin film has not formed with a first via hole 108 at a position of the first insulating layer 103. The first insulating layer 103 and the gate electrode insulating layer 203 can be of a single layer structure, and can also be of a multi-layer structure, such as silicon oxide/silicon nitride.

S103: forming the semiconductor pattern layer and the active layer on the base substrate where the first insulating thin film is formed;

The semiconductor pattern layer and the active layer are formed on the base substrate with the above first insulating thin film formed thereon;

A semiconductor thin film is deposited on the base substrate with the above first insulating thin film formed thereon, and for example, a material of the semiconductor thin film is amorphous silicon, polycrystalline silicon or metal oxides or the like. Then a single patterning process (including photoresist coating, exposure, development, etching, photoresist stripping and other steps) is executed on the semiconductor thin film so as to form the semiconductor pattern layer 121 and the active layer 204 which are on the same layer and formed by the same material. Herein, the semiconductor pattern layer 121 includes the fifth via hole 122 formed therein.

S104: forming the second conductive layer and the source electrode and the drain electrode on the base substrate with the semiconductor pattern layer and the active layer formed thereon.

A second metal thin film is formed on the base substrate 101 with the semiconductor pattern layer 121 and the active layer 204 formed thereon in a sputtering deposition manner, and for example, a material of the second metal thin film is Cu, Al, Mo, Ti, Cr, W or an alloy of the metal materials; then, a single patterning process (including photoresist coating, exposure, development, etching, photoresist stripping and other steps) is executed on the second metal thin film so as to form the second conductive layer 104 and the source electrode and the drain electrode 205 which are on the same layer and formed by the same material. Herein, for example, the second conductive layer 104 includes a second via hole 109. The second conductive layer 104 and the source electrode and the drain electrode 205 can be of a single layer structure, and can also be of a multi-layer structure, such as, Mo/Al/Mo, Ti/Cu/Ti, MoTi/Cu, Ti/Cu/Mo and the like.

S105: forming a second insulating thin film on the base substrate with the second conductive layer and the source electrode and the drain electrode formed thereon.

The second insulating thin film is formed on the base substrate 101 with the second conductive layer 104 and the source electrode and the drain electrode 205 formed thereon. The second insulating thin film can also be formed by depositing silicon nitride or silicon oxide by means of a PECVD process. The second insulating thin film can be used for further forming the passivation layer 206 subsequently and forming the second insulating layer 105 subsequently. When the step is completed, the second insulating thin film has not formed with a third via hole 110 at a position of the second insulating layer 105, and has not formed with a passivation layer via hole H above the drain electrode 25. The second insulating layer 105 and the passivation layer 206 formed by the second insulating thin film can be of a single layer structure, and can also be of a multi-layer structure, such as silicon oxide/silicon nitride, and an organic insulating layer can also be adopted, such as an organic resin material and the like.

S106: forming the passivation layer via hole and a recessed portion on the base substrate with the second insulating thin film formed thereon.

A patterning process is performed on the base substrate 101 with the above second insulating thin film formed thereon so as to form the passivation layer via hole H above the drain electrode 206 and the recessed portion 107″. Before the patterning process is executed, the second via hole 109 in the second conductive layer 104 and the fifth via hole in the semiconductor pattern layer 121 have been formed. The third via hole 110 in the second insulating layer 105 and the first via hole 108 in the first insulating layer 103 can be formed by adopting same etching solution or different etching solution as required; when the patterning process is executed, a dry etching process can also be adopted to form the passivation layer via hole H, the third via hole 110 in the second insulating layer 105 and the first via hole 108 in the first insulating layer 103. After the step is executed, part of an upper surface of the first conductive layer 102 is exposed, and part of an upper surface of the drain electrode 205 is exposed.

S107: forming the conductive connection component and the pixel electrode on the base substrate with the passivation layer via hole and the recessed portion formed thereon;

The conductive connection component 111 and the pixel electrode 207 are formed on the base substrate 101 with the passivation layer via hole H above the drain electrode 206 and the recessed portion 107″ formed on. For example, the conductive connection component 111 and the pixel electrode 207 are formed by sputtering a transparent metal oxide conductive material layer such as Indium tin oxide (ITO) and the like, then performing a single patterning process.

It can be known from the above description that, extra process steps need not to be added for forming the array substrate of the embodiment, and by means of a process for forming the pixel unit 400, the layer stacking structure provided by the embodiments of the present disclosure can be correspondingly formed.

### Embodiment VI

The embodiment provides a display device, including the array substrate provided by any one of the above embodiments.

One example of the display device is a liquid crystal display device, wherein, the array substrate and a counter substrate are opposed to each other to form a liquid crystal cell, and the liquid crystal cell is filled with a liquid crystal material. The counter substrate is, for example, a color filter substrate. A pixel electrode of each pixel unit of the array substrate is used for applying an electric field to control orientation of the liquid crystal material, That is, a rotation degree, an inclination degree or a rotation and inclination degree of liquid crystal molecules are controlled so as to perform display operation. In some examples, the liquid crystal display device further includes a backlight source providing backlight for the array substrate.

Another example of the display device is an organic electroluminescence display device, wherein, a pixel electrode of each pixel unit of the array substrate is used for driving an organic light-emitting material to emit light so as to perform display operation as an anode or a cathode.

What can be understood is that, the layer stacking structure provided by the present disclosure is not only limited to be applied to the array substrate of the display device. In fact, the layer stacking structure can be applied to any case that two conductive layers located in different layers need to be electrically connected. For example, in a printed circuit board, the layer stacking structure provided by the present disclosure can be adopted to connect two conductive layers located in different layers.

What are described above are only specific embodiments of the present invention, and the protection scope of the present invention is not limited thereto. It shall easily occur to any one person skilled in the art within the technical scope of the disclosure of the present invention that various changes or replacements shall be covered within the scope of the present invention. Therefore, the scope of the present invention should be the scope of the following claims.

The present application claims priority of Chinese Patent Application No. 201620126200.6 filed on Feb. 17, 2016, the disclosure of which is incorporated herein by reference in its entirety as part of the present application.

1. A layer stacking structure, comprising:
a base substrate;
a first conductive layer, a first insulating layer, a second conductive layer and a second insulating layer sequentially stacked in a direction away from the base substrate, wherein, the first conductive layer and the second conductive layer overlap with each other in an overlapping region;
a recessed portion arranged in the overlapping region, including:
a first via hole passing through the first insulating layer;
a second via hole passing through the second conductive layer; and
a third via hole passing through the second insulating layer,
wherein, the first via hole, the second via hole and the third via hole are communicated with each other; and
a conductive connection component, extending to pass through the third via hole, the second via hole and the first via hole of the recessed portion, wherein, the first conductive layer and the second conductive layer are electrically connected with each other through the conductive connection component,
wherein, the second conductive layer has at least one protrusion portion protruding towards an interior of the second via hole on a sidewall of the second via hole.

2. The layer stacking structure according to claim 1, wherein, the conductive connection component is in direct contact with the second conductive layer on the sidewall of the second via hole, and the conductive connection component is in direct contact with an upper surface of the first conductive layer at a bottom of the first via hole.

3. The layer stacking structure according to claim 1, wherein, an orthogonal projection of the second via hole on the base substrate is located within an orthogonal projection of the third via hole on the base substrate, and the conductive connection component is in direct contact with an upper surface of the second conductive layer at a bottom of the third via hole.

4. The layer stacking structure according to claim 1, wherein, the orthogonal projection of the second via hole on the base substrate is located within a orthogonal projection of the first via hole on the base substrate, and the conductive connection component is in direct contact with a lower surface of the second conductive layer at a top of the first via hole.

5. The layer stacking structure according to claim 1, wherein, the recessed portion further includes a fourth via hole passing through the first conductive layer, the fourth via hole is communicated with the first via hole, and the conductive connection component extends to pass through the fourth via hole so as to be in direct contact with an upper surface of the base substrate at a bottom of the fourth via hole.

6. The layer stacking structure according to claim 1, wherein, the first via hole, the second via hole and the third via hole are completely filled by the conductive connection component.

7. The layer stacking structure according to claim 1, wherein, the second via hole has a first sidewall and a second sidewall opposite to each other, the at least one protrusion portion includes at least one first protrusion portion protruding towards the second sidewall on the first sidewall, and at least one second protrusion portion protruding towards the first sidewall on the second sidewall.

8. The layer stacking structure according to claim 7, wherein, the second via hole further has a third sidewall and a fourth sidewall opposite to each other, the at least one protrusion portion further includes at least one third protrusion portion protruding towards the fourth sidewall on the third sidewall, and at least one fourth protrusion portion protruding towards the third sidewall on the fourth sidewall.

9. The layer stacking structure according to claim 8, wherein, the first protrusion portion, the second protrusion portion, the third protrusion portion and the fourth protrusion portion are not in contact with each other.

10. The layer stacking structure according to claim 1, wherein, the orthogonal projection of the first via hole on the base substrate coincides with the orthogonal projection of the second via hole on the base substrate.

11. The layer stacking structure according to claim 1, wherein, the conductive connection component is formed by a transparent conductive metal oxide.

12. The layer stacking structure according to claim 1, wherein, a planar shape of the at least one protrusion portion is square, rectangular, semicircular or polygonal.

13. The layer stacking structure according to claim 1, wherein, the first via hole, the second via hole and the third via hole are partially filled with the conductive connection component.

14. An array substrate, comprising the layer stacking structure according to claim 1, and a pixel unit formed on the base substrate, wherein, the pixel unit is located in a display region of the base substrate, and the layer stacking structure is located in a peripheral circuit region surrounding the display region.

15. The array substrate according to claim 14, wherein, the pixel unit includes a thin film transistor and a pixel electrode, the thin film transistor includes a gate electrode, a gate electrode insulating layer, an active layer, a source electrode and a drain electrode, and a passivation layer sequentially stacked in the direction away from the base substrate, the first conductive layer and the gate electrode are arranged on a same layer and are formed by a same material, the first insulating layer and the gate electrode insulating layer are on a same layer, the second conductive layer and the source electrode and the drain electrode are arranged on a same layer and are formed by a same material, the second insulating layer and the passivation layer are on a same layer, and the conductive connection component and the pixel electrode are formed by a same material.

16. The array substrate according to claim 15, wherein, a semiconductor pattern layer is further arranged between the second conductive layer and the first insulating layer, the semiconductor pattern layer and the active layer are arranged on a same layer and are formed by a same material, the recessed portion further includes a fifth via hole passing through the semiconductor pattern layer, the fifth via hole is communicated with the first via hole and the second via hole, and the conductive connection component extends to pass through the fifth via hole.

17. A display device, comprising the array substrate according to claim 14.

18. The layer stacking structure according to claim 2, wherein, an orthogonal projection of the second via hole on the base substrate is located within an orthogonal projection of the third via hole on the base substrate, and the conductive connection component is in direct contact with an upper surface of the second conductive layer at a bottom of the third via hole.

19. The layer stacking structure according to claim 2, wherein, the orthogonal projection of the second via hole on the base substrate is located within a orthogonal projection of the first via hole on the base substrate, and the conductive connection component is in direct contact with a lower surface .of the second conductive layer at a top of the first via hole.

20. The layer stacking structure according to claim 2, wherein, the recessed portion further includes a fourth via hole passing through the first conductive layer, the fourth via hole is communicated with the first via hole, and the conductive connection component extends to pass through the fourth via hole so as to be in direct contact with an upper surface of the base substrate at a bottom of the fourth via hole.
